(19) United States
(12) Patent Application Publication
(10) Pub. No.: US 2026/0047188 A1
(43) Pub. Date: Feb. 12, 2026

(54) SEMICONDUCTOR DEVICE

(71) Applicant: SAMSUNG ELECTRONICS CO., LTD., Suwon-si (KR)

(72) Inventors: Seo Woo NAM, Suwon-si (KR); Heon Jong Shin, Suwon-si (KR); Hye Young Park, Suwon-si (KR)

(73) Assignee: SAMSUNG ELECTRONICS CO., LTD., Suwon-si (KR)

(21) Appl. No.: 19/077,947

(22) Filed: Mar. 12, 2025

(30) Foreign Application Priority Data
Aug. 8, 2024 (KR) 10-2024-0106113

(51) Int. Cl. H10D 84/80; H10D 30/00; H10D 30/01; H10D 30/43; H10D 62/10; H10D 62/13; H10D 62/83

(52) U.S. Cl. CPC H10D 84/813; H10D 30/43; H10D 30/502; H10D 62/121; H10D 62/151; H10D 62/83; H10D 30/014; H10D 30/0191

(57) ABSTRACT

A semiconductor device includes a first region in which a passive element is provided, a second region adjacent to the first region and in which an active element is provided, a lower interlayer insulating layer in the first region and the second region, an insulating pattern in the second region and on an upper surface of the lower interlayer insulating layer, the insulating pattern extending in a first direction, a substrate in the first region, on the upper surface of the lower interlayer insulating layer, and spaced apart from the insulating pattern in the first direction, the substrate including silicon, and a field insulating layer in the second region and on the upper surface of the lower interlayer insulating layer, the field insulating layer at least partially surrounding a sidewall of the insulating pattern.

### CROSS-REFERENCE TO RELATED APPLICATION

This application is based on and claims priority to Korean Patent Application No. 10-2024-0106113, filed on Aug. 8, 2024, in the Korean Intellectual Property Office, the disclosure of which is incorporated by reference herein in its entirety.

### BACKGROUND

The present disclosure relates to a semiconductor device, and more particularly, to a semiconductor device including an MBCFET™ (Multi-Bridge Channel Field Effect Transistor).

As one of scaling technologies for increasing density of an integrated circuit device, a multi-gate transistor in which a silicon body having a fin shape or a nanowire shape is formed on a substrate and a gate is formed on a surface of the silicon body has been proposed.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device in which an active element and a passive element are disposed to be adjacent to each other, and in which a substrate formed on the passive element may be prevented from being etched during formation of the active element to improve the reliability of the passive element.

Additional aspects will be set forth in part in the description which follows and, in part, will be apparent from the description, or may be learned by practice of the presented embodiments.

According to an aspect of an example embodiment, a semiconductor device may include a first region in which a passive element is provided, a second region adjacent to the first region and in which an active element is provided, a lower interlayer insulating layer in the first region and the second region, an insulating pattern in the second region and on an upper surface of the lower interlayer insulating layer, the insulating pattern extending in a first direction, a substrate in the first region, on the upper surface of the lower interlayer insulating layer, and spaced apart from the insulating pattern in the first direction, the substrate including silicon, a field insulating layer in the second region and on the upper surface of the lower interlayer insulating layer, the field insulating layer at least partially surrounding a sidewall of the insulating pattern, a plurality of nanosheets on the insulating pattern and spaced apart from each other in a second direction that is perpendicular to the first direction, a gate electrode on the insulating pattern and extending in a third direction that intersects the first direction, the gate electrode at least partially surrounding the plurality of nanosheets, and an element isolation layer on a boundary line between the first region and the second region and on the upper surface of the lower interlayer insulating layer, where the element isolation layer includes a material that is different from a material of the field insulating layer, and in the second direction, a lower surface of the element isolation layer is at a level that is lower than a level of a lower surface of the field insulating layer.

According to an aspect of an example embodiment, a semiconductor device may include a first region in which a passive element is provided, a second region surrounding the first region and in which an active element is provided, a lower interlayer insulating layer in the first region and the second region, an insulating pattern in the second region and on an upper surface of the lower interlayer insulating layer, the insulating pattern extending in a first direction, a substrate in the first region, on the upper surface of the lower interlayer insulating layer and spaced apart from the insulating pattern in the first direction, the substrate including silicon, a field insulating layer in the second region and on the upper surface of the lower interlayer insulating layer, the field insulating layer at least partially surrounding a sidewall of the insulating pattern, a gate electrode on the insulating pattern and extending in a second direction that intersects the first direction, a source/drain region on the insulating pattern, a source/drain contact connected to the source/drain region and penetrating the lower interlayer insulating layer and the insulating pattern in a third direction that is perpendicular to the first direction and the second direction, and an element isolation layer on a boundary line between the first region and the second region and on the upper surface of the lower interlayer insulating layer, where the element isolation layer includes a material that is different from a material of the field insulating layer, a lower surface of the element isolation layer is at a level that is lower than a level of a lower surface of the field insulating layer in the third direction, the lower surface of the element isolation layer is substantially coplanar with a lower surface of the substrate, the element isolation layer extends downward in the third direction to a first level, and the source/drain contact extends downward in the third direction to a second level that is lower than the first level.

According to an aspect of an example embodiment, a semiconductor device may include a first region in which a passive element is provided, a second region surrounding the first region and in which an active element is provided, a lower interlayer insulating layer in the first region and the second region, an insulating pattern in the second region and on an upper surface of the lower interlayer insulating layer, the insulating pattern extending in a first direction, a substrate in the first region, on the upper surface of the lower interlayer insulating layer, and spaced apart from the insulating pattern in the first direction, where the substrate includes silicon, and an upper surface of the substrate is at a level that is higher than a level of an uppermost surface of the insulating pattern in a second direction that is perpendicular to the first direction, a field insulating layer in the second region and on the upper surface of the lower interlayer insulating layer, the field insulating layer at least partially surrounding a sidewall of the insulating pattern, a plurality of nanosheets on the insulating pattern and spaced apart from each other in the second direction, a gate electrode on the insulating pattern and extending in a third direction that intersects the first direction, the gate electrode at least partially surrounding the plurality of nanosheets, a gate spacer on both sidewalls of the gate electrode in the first direction, the gate spacer contacting sidewalls of the plurality of nanosheets that face the substrate in the first direction, a source/drain region on the insulating pattern, a source/drain contact connected to the source/drain region and penetrating the lower interlayer insulating layer and the insulating pattern in the second direction, and an element isolation layer on a boundary line between the first region and the second region and on the upper surface of the lower interlayer insulating layer, where the element isolation layer includes a material that is different from a material of the field insulating layer, a lower surface of the element isolation layer is at a level that is lower than a level of a lower surface of the field insulating layer in the second direction, the lower surface of the element isolation layer is substantially coplanar with lower surface of the substrate, an upper surface of the element isolation layer is at a level that is higher than a level of an uppermost surface of the gate electrode in the second direction, the element isolation layer extends downward in the second direction to a first level, and the source/drain contact extends downward in the second direction to a second level that is lower than the first level.

### BRIEF DESCRIPTION OF THE DRAWINGS

The above and other aspects, features, and advantages of certain example embodiments of the present disclosure will be more apparent from the following description taken in conjunction with the accompanying drawings, in which:

FIG. 1 is a diagram illustrating a semiconductor device according to one or more embodiments;

FIG. 2 is an enlarged view of a region R1 of FIG. 1 according to one or more embodiments;

FIG. 3 is a cross-sectional view taken along line A-A′ of FIG. 2 according to one or more embodiments;

FIG. 4 is a cross-sectional view taken along line B-B′ of FIG. 2 according to one or more embodiments;

FIGS. 5 to 26 are diagrams illustrating a method for fabricating a semiconductor device according to one or more embodiments;

FIG. 27 is a cross-sectional view illustrating a semiconductor device according to one or more embodiments;

FIG. 28 is a cross-sectional view illustrating a semiconductor device according to one or more embodiments;

FIG. 29 is a cross-sectional view illustrating a semiconductor device according to one or more embodiments;

FIG. 30 is a cross-sectional view illustrating a semiconductor device according to one or more embodiments; and

FIG. 31 is a diagram illustrating a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Although some drawings of a semiconductor device according to one or more embodiments will be described in which the semiconductor device includes a transistor ((Multi-Bridge Channel Field Effect Transistor (FET) (MBCFET™) including a nanosheet, embodiments are not limited thereto. In one or more embodiments, the semiconductor device may, of course, include a fin-shaped transistor (FinFET) including a channel region of a fin-type pattern shape, a tunneling transistor or a three-dimensional (3D) transistor. Further, the semiconductor device according to some other embodiments may, of course, include a bipolar junction transistor, a laterally diffused metal oxide semiconductor (LDMOS), or the like.

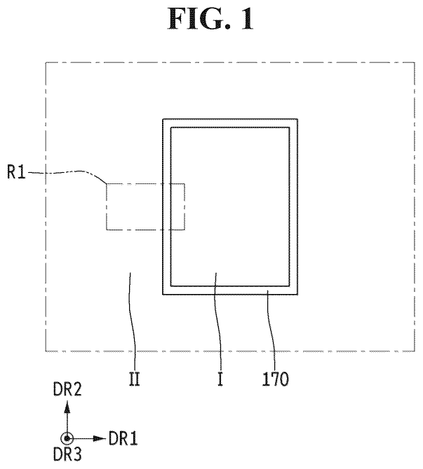

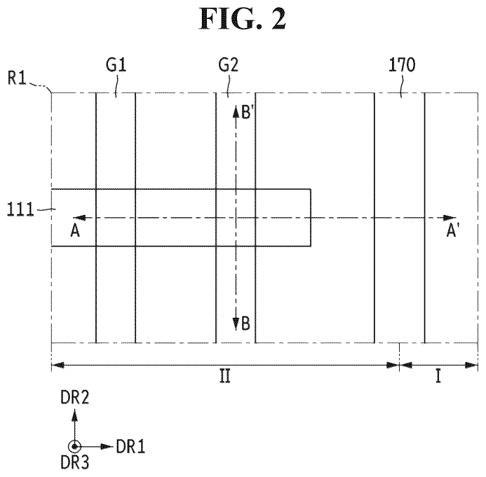

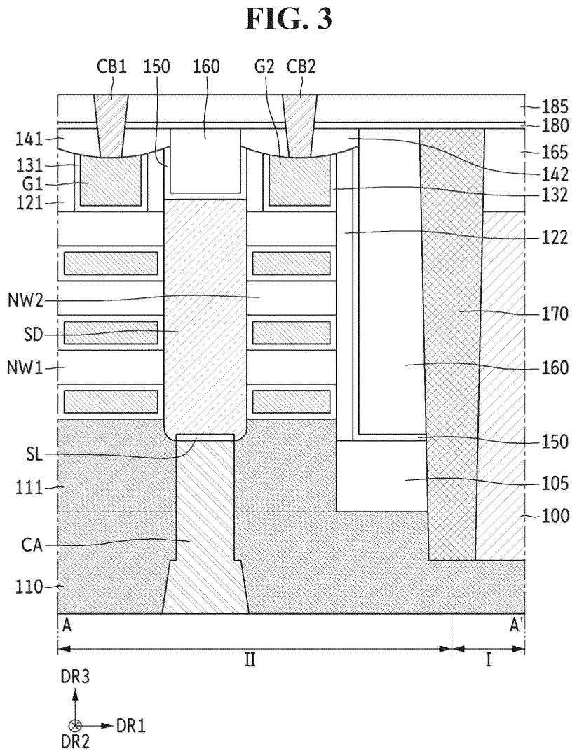

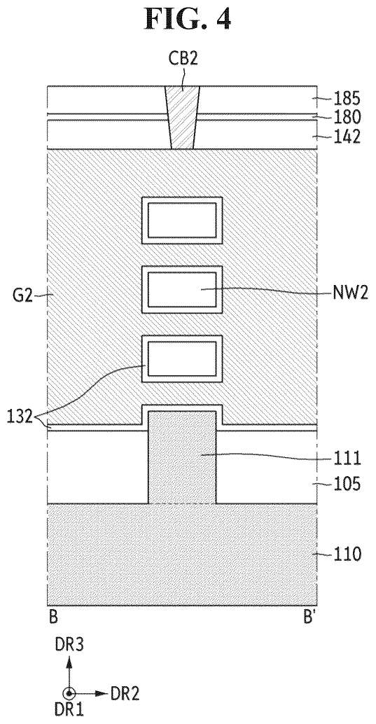

FIG. 1 is diagram illustrating a semiconductor device according to one or more embodiments. FIG. 2 is an enlarged view of a region R1 of FIG. 1 according to one or more embodiments. FIG. 3 is a cross-sectional view taken along line A-A′ of FIG. 2 according to one or more embodiments. FIG. 4 is a cross-sectional view taken along line B-B′ of FIG. 2 according to one or more embodiments.

Referring to FIG. 1, the semiconductor device according to one or more embodiments may include a first region I and a second region II. For example, the second region II may surround the first region I on a plane. For example, the first region I may be a region in which a passive element is disposed. For example, the passive element may be a resistor, an inductor or a capacitor. For example, the second region II may be a region in which an active element such as a transistor is disposed. For example, an element isolation layer 170 may be disposed along a boundary line between the first region I and the second region II. For example, the element isolation layer 170 may separate the first region I and the second region II on a plane. A detailed description of the element isolation layer 170 will be given later.

Referring to FIGS. 1 to 4, the semiconductor device according to one or more embodiments may include a substrate 100, a lower interlayer insulating layer 110, an insulating pattern 111, a field insulating layer 105, a first and second plurality of nanosheets NW1 and NW2, first and second gate electrodes G1 and G2, first and second gate spacers 121 and 122, first and second gate insulating layers 131 and 132, first and second capping patterns 141 and 142, a source/drain region SD, a first etching stop layer 150, a first upper interlayer insulating layer 160, a second upper interlayer insulating layer 165, an element isolation layer 170, a source/drain contact CA, a silicide layer SL, first and second gate contacts CB1 and CB2, a second etching stop layer 180, and a third upper interlayer insulating layer 185.

The lower interlayer insulating layer 110 may be disposed in the first region I and the second region II. For example, an uppermost surface of the lower interlayer insulating layer 110 disposed in the second region II may be at a level that is higher than an upper surface of the lower interlayer insulating layer 110 of the first region I in the direction DR3. For example, the lower interlayer insulating layer 110 may include at least one of silicon oxide, silicon nitride, silicon oxynitride, and a low dielectric constant material. The low dielectric constant material may include, for example, but not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica or combinations thereof.

Hereinafter, each of a first horizontal direction DR1 and a second horizontal direction DR2 is defined as a direction parallel to the upper surface of the lower interlayer insulating layer 110 disposed in the second region II. The second horizontal direction DR2 may be defined as a direction different from (intersecting) the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the uppermost surface of the lower interlayer insulating layer 110 disposed in the second region II.

The insulating pattern 111 may extend in the first horizontal direction DR1 on the upper surface of the lower interlayer insulating layer 110 disposed in the second region II. The insulating pattern 111 may protrude in the vertical direction DR3 from the upper surface of the lower interlayer insulating layer 110 disposed in the second region II. For example, the insulating pattern 111 may include the same material as the lower interlayer insulating layer 110. The field insulating layer 105 may surround a sidewall of the insulating pattern 111 on the upper surface of the lower interlayer insulating layer 110 disposed in the second region II. For example, the upper surface of the field insulating layer 105 may be at a level that is lower than the upper surface of the insulating pattern 111 in the direction DR3. For example, the field insulating layer 105 may contact the upper surface of the lower interlayer insulating layer 110 disposed in the second region II. For example, the field insulating layer 105 may contact each sidewall of the insulating pattern 111 in the first and second horizontal directions DR1 and DR2. For example, the field insulating layer 105 may include, for example, an oxide film, a nitride film, an oxynitride film or a combined film thereof.

The substrate 100 may be disposed on the upper surface of the lower interlayer insulating layer 110 disposed in the first region I. For example, the substrate 100 may be spaced apart from the insulating pattern 111 in the first horizontal direction DR1. For example, the substrate 100 may be spaced apart from the field insulating layer 105 in the first horizontal direction DR1. For example, the upper surface of the substrate 100 may be at a level that is higher than the upper surface of the field insulating layer 105 in the direction DR3. For example, the upper surface of the substrate 100 may be at a level that is higher than the uppermost surface of the insulating pattern 111 in the direction DR3. For example, the substrate 100 may include silicon (Si). In one or more embodiments, the substrate 100 may be a silicon-on-insulator (SOI). In one or more embodiments, although the substrate 100 may include silicon-germanium, silicon germanium on insulator (SGOI), indium antimonide, lead telluride, indium arsenide, indium phosphide, gallium arsenide or gallium antimonide, embodiments are not limited thereto.

Each of the first and second plurality of nanosheets NW1 and NW2 may be disposed in the second region II. For example, the second plurality of nanosheets NW2 may be disposed between the first plurality of nanosheets NW1 and the substrate 100. The second plurality of nanosheets NW2 may be spaced apart from the first plurality of nanosheets NW1 in the first horizontal direction DR1. The substrate 100 may be spaced apart from the second plurality of nanosheets NW2 in the first horizontal direction DR1. Each of the first and second plurality of nanosheets NW1 and NW2 may include a plurality of nanosheets stacked on the upper surface of the insulating pattern 111 to be spaced apart from each other in the vertical direction DR3.

Although FIGS. 3 and 4 show that each of the first and second plurality of nanosheets NW1 and NW2 includes three nanosheets stacked to be spaced apart from each other in the vertical direction DR3, this is only for convenience of explanation, and embodiments are not limited thereto. In one or more embodiments, each of the first and second plurality of nanosheets NW1 and NW2 may include four or more nanosheets stacked to be spaced apart from each other in the vertical direction DR3. For example, each of the first and second plurality of nanosheets NW1 and NW2 may include silicon (Si).

Each of the first and second gate electrodes G1 and G2 may be disposed in the second region II. Each of the first and second gate electrodes G1 and G2 may extend in the second horizontal direction DR2 on the insulating pattern 111 and the field insulating layer 105. For example, the second gate electrode G2 may be disposed between the first gate electrode G1 and the substrate 100. The second gate electrode G2 may be spaced apart from the first gate electrode G1 in the first horizontal direction DR1. The substrate 100 may be spaced apart from the second gate electrode G2 in the first horizontal direction DR1. The first gate electrode G1 may surround the first plurality of nanosheets NW1. The second gate electrode G2 may surround the second plurality of nanosheets NW2.

For example, each of the first and second gate electrodes G1 and G2 may include, for example, but not limited to, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. Each of the first and second gate electrodes G1 and G2 may include a conducive metal oxide, a conductive metal oxynitride or the like, and may include an oxide form of the aforementioned materials.

Each of the first and second gate spacers 121 and 122 may be disposed in the second region II. The first gate spacer 121 may extend in the second horizontal direction DR2 along sidewalls of the first gate electrode G1 on the upper surface of the uppermost nanosheet of the first plurality of nanosheets NW1 and the upper surface of the field insulating layer 105. The second gate spacer 122 may extend in the second horizontal direction DR2 along both sidewalls of the second gate electrode G2 on the upper surface of the uppermost nanosheet of the second plurality of nanosheets NW2 and the upper surface of the field insulating layer 105.

For example, a portion of the second gate spacer 122 may be disposed on a first sidewall of the second gate electrode G2 that faces the first gate electrode G1. A portion of the second gate spacer 122 disposed on the first sidewall of the second gate electrode G2 may contact the upper surface of the uppermost nanosheet of the second plurality of nanosheets NW2. For example, another portion of the second gate spacer 122 may be disposed on a second sidewall of the second gate electrode G2 that faces the substrate 100. The other portion of the second gate spacer 122 disposed on the second sidewall of the second gate electrode G2 may contact the sidewall in the first horizontal direction DR1 of the second plurality of nanosheets NW2 that face the substrate 100. For example, each of the first and second gate spacers 121 and 122 may include, but not limited to, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. However, embodiments are not limited thereto.

The source/drain region SD may be disposed in the second region II. The source/drain region SD may be disposed on one side of the second gate electrode G2 on the insulating pattern 111. For example, the source/drain region SD may be disposed between the first gate electrode G1 and the second gate electrode G2 on the insulating pattern 111. The source/drain region SD may contact the sidewalls of the first and second plurality of nanosheets NW1 and NW2 in the first horizontal direction DR1.

Each of the first and second gate insulating layers 131 and 132 may be disposed in the second region II. The first gate insulating layer 131 may be disposed between the first gate electrode G1 and the insulating pattern 111. The first gate insulating layer 131 may be disposed between the first gate electrode G1 and the first plurality of nanosheets NW1. The first gate insulating layer 131 may be disposed between the first gate electrode G1 and the source/drain region SD. The first gate insulating layer 131 may be disposed between the first gate electrode G1 and the first gate spacer 121. The second gate insulating layer 132 may be disposed between the second gate electrode G2 and the insulating pattern 111. The second gate insulating layer 132 may be disposed between the second gate electrode G2 and the second plurality of nanosheets NW2. The second gate insulating layer 132 may be disposed between the second gate electrode G2 and the source/drain region SD. The second gate insulating layer 132 may be disposed between the second gate electrode G2 and the second gate spacer 122.

Each of the first and second gate insulating layers 131 and 132 may include at least one of silicon oxide, silicon oxynitride, silicon nitride and a high dielectric constant material having a higher dielectric constant than silicon oxide. The high dielectric constant material may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

The semiconductor device according to one or more embodiments may include a Negative Capacitance FET (NCFET) that uses a negative capacitor. For example, each of the first and second gate insulating layers 131 and 132 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium CA, cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 at% (atomic %) aluminum. Here, a ratio of the dopant may be a ratio of aluminum to the sum of hafnium and aluminum.

When the dopant is silicon (Si), the ferroelectric material film may include 2 to 10 at% silicon. When the dopant is yttrium (Y), the ferroelectric material film may include 2 to 10 at% yttrium. When the dopant is gadolinium (Gd), the ferroelectric material film may include 1 to 7 at% gadolinium. When the dopant is zirconium (Zr), the ferroelectric material film may include 50 to 80 at% zirconium.

The paraelectric material film may have the paraelectric properties. The paraelectric material film may include, for example, at least one of silicon oxide and a metal oxide having a high dielectric constant. The metal oxide included in the paraelectric material film may include, for example, but not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, but not limited to, 0.5 to 10 nm. Since a critical thickness that exhibits the ferroelectric properties may vary for each ferroelectric material, the thickness of the ferroelectric material film may vary depending on the ferroelectric material.

As an example, each of the first and second gate insulating layers 131 and 132 may include one ferroelectric material film. As another example, each of the first and second gate insulating layers 131 and 132 may include a plurality of ferroelectric material films spaced apart from each other. Each of the first and second gate insulating layers 131 and 132 may have a stacked film structure in which a plurality of ferroelectric material films and a plurality of paraelectric material films are alternately stacked.

The first etching stop layer 150 may be disposed in the second region II. The first etching stop layer 150 may be disposed on the sidewalls of each of the first and second gate spacers 121 and 122 in the first horizontal direction DR1. The first etching stop layer 150 may be disposed on the upper surface of the field insulating layer 105. The first etching stop layer 150 may be disposed on the upper surface of the source/drain region SD. The first etching stop layer 150 may be disposed on the sidewalls of the source/drain region SD in the second horizontal direction DR2. For example, the first etching stop layer 150 may be formed conformally. For example, the first etching stop layer 150 may include at least one of aluminum oxide, aluminum nitride, hafnium oxide, zirconium oxide, silicon oxide, silicon nitride, silicon oxynitride, and a low dielectric constant material.

Each of the first and second capping patterns 141 and 142 may be disposed in the second region II. The first capping pattern 141 may extend in the second horizontal direction DR2 on each of the first gate spacer 121, the first gate insulating layer 131, and the first gate electrode G1. The second capping pattern 142 may extend in the second horizontal direction DR2 on each of the second gate spacer 122, the second gate insulating layer 132, and the second gate electrode G2. For example, the lower surfaces of each of the first and second capping patterns 141 and 142 may contact the first etching stop layer 150. However, embodiments are not limited thereto. In one or more embodiments, the sidewalls of each of the first and second capping patterns 141 and 142 may contact the first etching stop layer 150. Each of the first and second capping patterns 141 and 142 may include, for example, at least one of silicon nitride (SiN), silicon oxynitride (SiON), silicon oxide (SiO₂), silicon carbonitride (SiCN), silicon oxycarbonitride (SiOCN), and combinations thereof. However, embodiments are not limited thereto.

The first upper interlayer insulating layer 160 may be disposed in the second region II. The first upper interlayer insulating layer 160 may be disposed on the first etching stop layer 150. The first upper interlayer insulating layer 160 may be disposed on of the sidewalls of each of the first and second capping patterns 141 and 142. The first upper interlayer insulating layer 160 may cover the source/drain region SD on the field insulating layer 105. For example, the upper surface of the first upper interlayer insulating layer 160 may be formed on the same plane as (e.g., may be substantially coplanar with) the upper surfaces of each of the first and second capping patterns 141 and 142. For example, the first upper interlayer insulating layer 160 may include at least one of silicon oxide, silicon nitride, silicon oxynitride, and a low dielectric constant material. The second upper interlayer insulating layer 165 may be disposed in the first region I. The second upper interlayer insulating layer 165 may be disposed on the upper surface of the substrate 100. For example, the upper surface of the second upper interlayer insulating layer 165 may be formed on the same plane as (e.g., may be substantially coplanar with) the upper surface of the first upper interlayer insulating layer 160. However, embodiments are not limited thereto. For example, the second upper interlayer insulating layer 165 may include at least one of silicon oxide, silicon nitride, silicon oxynitride, and a low dielectric constant material.

The element isolation layer 170 may be disposed along a boundary line between the first region I and the second region II. For example, the element isolation layer 170 may separate the first region I and the second region II on a plane. For example, the lower surface of the element isolation layer 170 may contact the upper surface of the lower interlayer insulating layer 110. For example, the lower surface of the element isolation layer 170 may be formed on the same plane as (e.g., may be substantially coplanar with) the lower surface of the substrate 100. For example, the lower surface of the element isolation layer 170 may be at a level that is lower than the lower surface of the insulating pattern 111 in the direction DR3. For example, the lower surface of the element isolation layer 170 may be at a level that is lower than the lower surface of the field insulating layer 105 in the direction DR3.

The element isolation layer 170 may extend in the vertical direction DR3 from the upper surface of the lower interlayer insulating layer 110. For example, the upper surface of the element isolation layer 170 may be at a level that is higher than the upper surface of the field insulating layer 105 in the direction DR3. For example, the upper surface of the element isolation layer 170 may be at a level that is higher than the upper surface of the substrate 100 in the direction DR3. For example, the upper surface of the element isolation layer 170 may be at a level that is higher than the uppermost surfaces of each of the first and second gate electrodes G1 and G2 in the direction DR3. For example, the upper surface of the element isolation layer 170 may be formed on the same plane as (e.g., may be substantially coplanar with) each of the upper surface of the first upper interlayer insulating layer 160 and the upper surface of the second upper interlayer insulating layer 165.

For example, a first sidewall of the element isolation layer 170 may contact each of the lower interlayer insulating layer 110, the field insulating layer 105, the first etching stop layer 150, and the first upper interlayer insulating layer 160. For example, a second sidewall of the element isolation layer 170 that is opposite to the first sidewall of the element isolation layer 170 in the first horizontal direction DR1 may contact each of the substrate 100 and the second upper interlayer insulating layer 165. Although FIG. 3 shows that the lower interlayer insulating layer 110 is not disposed between the first sidewall of the element isolation layer 170 and the field insulating layer 105, embodiments are not limited thereto. In one or more embodiments, at least a portion of the lower interlayer insulating layer 110 may be disposed between the first sidewall of the element isolation layer 170 and the field insulating layer 105.

For example, a width of the upper surface of the element isolation layer 170 in the first horizontal direction DR1 may be greater than a width of the lower surface of the element isolation layer 170 in the first horizontal direction DR1. For example, the width of the element isolation layer 170 in the first horizontal direction DR1 may continuously increase from the lower surface of the element isolation layer 170 toward the upper surface of the element isolation layer 170. For example, the element isolation layer 170 may include a material different from the field insulating layer 105. For example, the element isolation layer 170 may include, for example, at least one of silicon nitride (SiN), silicon oxide (SiO₂), silicon oxynitride (SiON), silicon carbide (SiC), silicon carbonitride (SiCN), silicon oxycarbide (SiOC), and silicon oxycarbonitride (SiOCN).

The second etching stop layer 180 may be disposed on the upper surfaces of each of the first and second capping patterns 141 and 142, the first and second upper interlayer insulating layers 160 and 165, and the element isolation layer 170. For example, the second etching stop layer 180 may be formed conformally. Although the second etching stop layer 180 is shown as being formed as a single film in FIGS. 3 and 4, embodiments are not limited thereto. In one or more embodiments, the second etching stop layer 180 may be formed as a multi-layer film. For example, the second etching stop layer 180 may include at least one of aluminum oxide, aluminum nitride, hafnium oxide, zirconium oxide, silicon oxide, silicon nitride, silicon oxynitride, and a low dielectric constant material. The third upper interlayer insulating layer 185 may be disposed on the second etching stop layer 180. For example, the third upper interlayer insulating layer 185 may include at least one of silicon oxide, silicon nitride, silicon oxynitride, and a low dielectric constant material.

The source/drain contact CA may be disposed in the second region II. The source/drain contact CA may be disposed below the source/drain region SD. The source/drain contact CA may penetrate the lower interlayer insulating layer 110 and the insulating pattern 111 in the vertical direction DR3, and may be electrically connected to the source/drain region SD. For example, the lower surface of the source/drain contact CA may be formed on the same plane as (e.g., may be substantially coplanar with) the lower surface of the lower interlayer insulating layer 110. For example, the element isolation layer 170, as well as the substrate 100 may extend downward in the vertical direction DR3 to a first level, and the source. /drain contact CA may extend downward in the vertical direction DR3 to a second level that is lower than the first level. In one or more embodiments, the element isolation layer 170 may extend downward in the vertical direction DR3 to a first level, the substrate 100 may extend downward in the vertical direction DR3 to a second level that is different from the first level, and the source/drain contact CA may extend downward in the vertical direction DR3 to a third level that is lower than the first level and the second level.

In FIG. 3, the source/drain contact CA is shown as being formed as a single film, but embodiments are not limited thereto. In one or more embodiments, the source/drain contact CA may be formed as a multi-layer film. The source/drain contact CA may include a conductive material. The silicide layer SL may be disposed between the source/drain contact CA and the source/drain region SD. For example, the silicide layer SL may be disposed along an interface between the source/drain contact CA and the source/drain region SD. For example, the silicide layer SL may include a metal silicide material.

The first gate contact CB1 may penetrate the third upper interlayer insulating layer 185, the second etching stop layer 180, and the first capping pattern 141 in the vertical direction DR3, and may be connected to the first gate electrode G1. The second gate contact CB2 may penetrate the third upper interlayer insulating layer 185, the second etching stop layer 180, and the second capping pattern 142 in the vertical direction DR3, and may be connected to the second gate electrode G2. Although each of the first and second gate contacts CB1 and CB2 is shown as being formed as a single film in FIGS. 3 and 4, embodiments are not limited thereto. In one or more embodiments, each of the first and second gate contacts CB1 and CB2 may be formed as a multi-layer film. Each of the first and second gate contacts CB1 and CB2 may include a conductive material.

Hereinafter, a method for fabricating a semiconductor device according to one or more embodiments will be described referring to FIGS. 3 to 26.

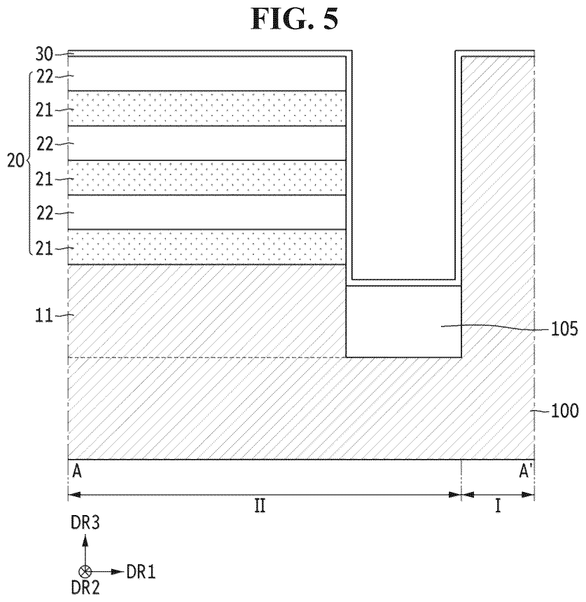

FIGS. 5 to 26 are diagrams illustrating a method for fabricating a semiconductor device according to one or more embodiments.

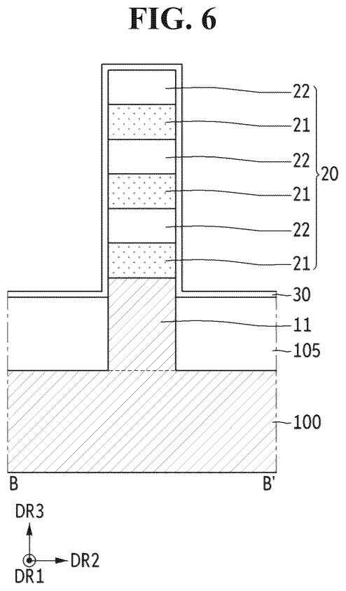

Referring to FIGS. 5 and 6, a substrate 100 may be provided. The substrate 100 may be formed in both the first region I and the second region II. Then, a portion of the substrate 100 formed in the second region II may be etched. Next, a stacked structure 20 may be formed on the upper surface of the etched substrate 100 in the second region II. The stacked structure 20 may include first semiconductor layers 21 and second semiconductor layers 22 that are alternately stacked on the upper surface of the substrate 100 in the second region II. For example, one of the first semiconductor layers 21 may be formed at the lowermost portion of the stacked structure 20, and one of the second semiconductor layers 22 may be formed at the uppermost portion of the stacked structure 20. However, embodiments are not limited thereto. In one or more embodiments, one of the first semiconductor layers 21 may also be formed on the uppermost portion of the stacked structure 20. In FIG. 5, although the upper surface of the stacked structure 20 is shown as being at the same height as the upper surface of the substrate 100 formed in the first region I, embodiments are not limited thereto. For example, the first semiconductor layer 21 may include silicon germanium (SiGe), and the second semiconductor layer 22 may include silicon (Si).

Next, a portion of the stacked structure 20 may be etched. While the stacked structure 20 is being etched, a portion of the substrate 100 formed in the second region II may also be etched. An active pattern 11 may be defined below the stacked structure 20 on the upper surface of the substrate 100 formed in the second region II through such an etching process. The active pattern 11 may protrude in the vertical direction DR3 from the upper surface of the substrate 100 formed in the second region II. The active pattern 11 may extend in the first horizontal direction DR1. For example, the active pattern 11 may include silicon (Si).

Next, the field insulating layer 105 may be formed on the upper surface of the substrate 100 formed in the second region II. The field insulating layer 105 may surround a sidewall of the active pattern 11. The field insulating layer 105 may contact the sidewall of the active pattern 11. Also, the field insulating layer 105 may contact a sidewall of the substrate 100 formed in the first region I. For example, the upper surface of the field insulating layer 105 may be at a level that is lower than the upper surface of the active pattern 11 in the direction DR3. Next, a pad oxide layer 30 may be formed to cover the upper surface of the field insulating layer 105, the exposed sidewall of the active pattern 11, and the sidewall and upper surface of the stacked structure 20. Also, the pad oxide layer 30 may be formed to cover the exposed sidewall and upper surface of the substrate 100 formed in the first region I. For example, the pad oxide layer 30 may be formed conformally. For example, the pad oxide layer 30 may include silicon oxide (SiO₂).

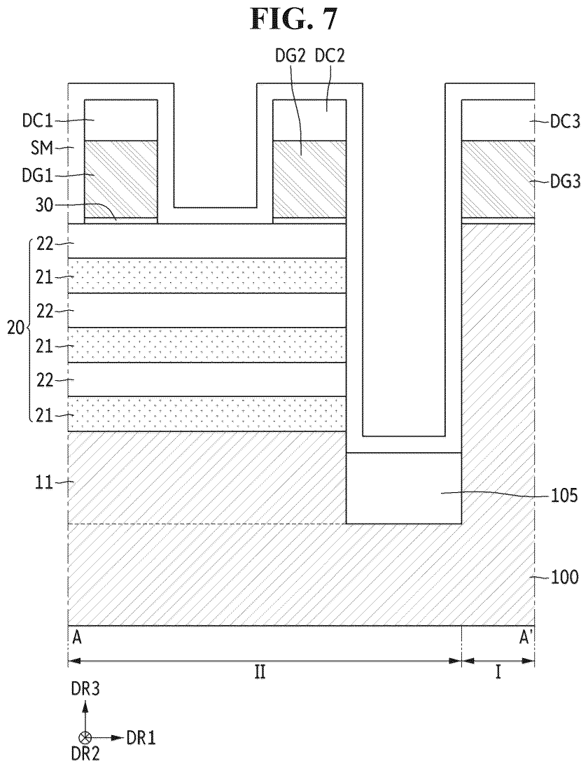

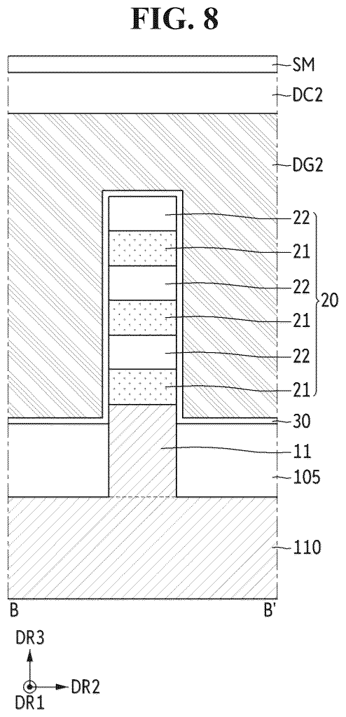

Referring to FIGS. 7 and 8, first and second dummy gates DG1 and DG2 and first and second dummy capping patterns DC1 and DC2 extending in the second horizontal direction DR2 on the pad oxide layer 30 may be formed on the stacked structure 20 and the field insulating layer 105. For example, the second dummy gate DG2 may be spaced apart from the first dummy gate DG1 in the first horizontal direction DR1. The first dummy capping pattern DC1 may be disposed on the first dummy gate DG1. The second dummy capping pattern DC2 may be disposed on the second dummy gate DG2. Also, a third dummy gate DG3 and a third dummy capping pattern DC3 may be formed on the pad oxide layer 30 over the upper surface of the substrate 100 formed in the first region I. For example, the third dummy gate DG3 may be spaced apart from the second dummy gate DG2 in the first horizontal direction DR1. For example, the third dummy gate DG3 may be formed to cover the entire upper surface of the substrate 100 formed in the first region I. The third dummy capping pattern DC3 may be disposed on the third dummy gate DG3. While the first to third dummy gates DG1, DG2 and DG3 and the first to third dummy capping patterns DC1, DC2 and DC3 are being formed, the remaining pad oxide layer 30 except for the portions that are overlapped by each of the first to third dummy gates DG1, DG2 and DG3 in the vertical direction DR3 may be removed.

Next, a spacer material layer SM may be formed to cover the sidewalls of each of the first to third dummy gates DG1, DG2 and DG3, the sidewalls and upper surfaces of each of the first to third dummy capping patterns DC1, DC2 and DC3, the exposed sidewall and upper surface of the stacked structure 20, the upper surface of the field insulating layer 105, and the exposed sidewalls of the substrate 100 formed in the first region I. For example, the spacer material layer SM may be formed conformally. The spacer material layer SM may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof.

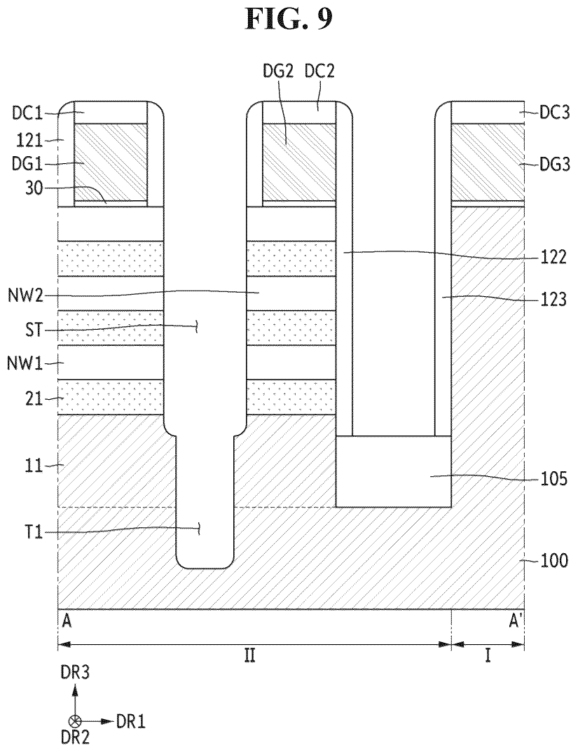

Referring to FIG. 9, the stacked structure (20 of FIG. 7) may be etched using the first to third dummy gates DG1, DG2, and DG3 and the first to third dummy capping patterns DC1, DC2, and DC3 as a mask to form a source/drain trench ST. The source/drain trench ST may be formed between the first dummy gate DG1 and the second dummy gate DG2 on the active pattern 11. In addition, a sacrificial pattern trench T1 may be formed below the source/drain trench ST. For example, the sacrificial pattern trench T1 may by penetrate the active pattern 11 in the vertical direction DR3 and extend into the substrate 100. For example, while the source/drain trench ST and the sacrificial pattern trench T1 are being formed, the spacer material layer (SM of FIG. 7) formed on the upper surface of each of the first to third dummy capping patterns DC1, DC2, and DC3, the spacer material layer (SM of FIG. 7) formed on the upper surface of the field insulating layer 105, and a portion of each of the first to third dummy capping patterns DC1, DC2, and DC3 may be etched. For example, after the source/drain trench ST and the sacrificial pattern trench T1 are formed, the second semiconductor layer (22 of FIG. 7) that remains below the first dummy gate DG1 may be defined as the first plurality of nanosheets NW1. After the source/drain trench ST and the sacrificial pattern trench T1 are formed, the second semiconductor layer (22 of FIG. 7) that remains below the second dummy gate DG2 may be defined as the second plurality of nanosheets NW2.

For example, after the source/drain trench ST and the sacrificial pattern trench T1 are formed, the spacer material layer (SM of FIG. 7) that remains on the sidewalls of each of the first dummy capping pattern DC1 and the first dummy gate DG1 may be defined as a first gate spacer 121. After the source/drain trench ST and the sacrificial pattern trench T1 are formed, the spacer material layer (SM of FIG. 7) that remains on the sidewalls of each of the second dummy capping pattern DC2 and the second dummy gate DG2 may be defined as a second gate spacer 122. For example, the second gate spacer 122 may also be formed on the sidewalls in the first horizontal direction DR1 of each of the second plurality of nanosheets NW2 and the first semiconductor layer 21 that face the substrate 100 formed in the region I. After the source/drain trench ST and the sacrificial pattern trench T1 are formed, the spacer material layer (SM of FIG. 7) that remains on sidewall of each of the third dummy capping pattern DC3 and the third dummy gate DG3 may be defined as a dummy gate spacer 123. For example, the dummy gate spacer 123 may also be formed on the exposed sidewall of the substrate 100 formed in the first region I.

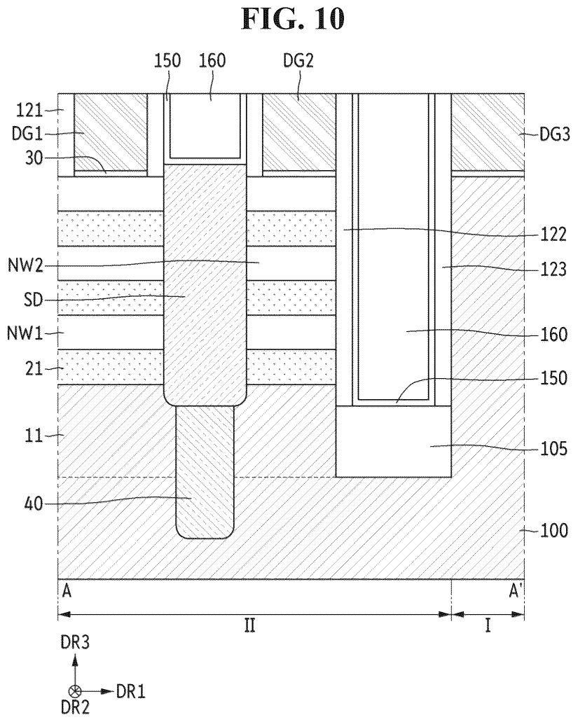

Referring to FIG. 10, the sacrificial pattern 40 may be formed inside the source/drain trench (T1 of FIG. 9). Next, a source/drain region SD may be formed inside the source/drain trench (ST of FIG. 9). Next, the first etching stop layer 150 may be formed on the exposed upper surface of the field insulating layer 105, the exposed sidewalls of each of the first and second gate spacers 121 and 122, the exposed sidewall of the dummy gate spacer 123, the exposed upper surfaces of each of the first to third dummy capping patterns (DC1, DC2, and DC3 of FIG. 9), and the exposed surface of the source/drain region SD. Next, a first upper interlayer insulating layer 160 may be formed on the etching stop layer 150. Next, a planarization process may be performed to expose the upper surfaces of each of the first to third dummy gates DG1, DG2, and DG3.

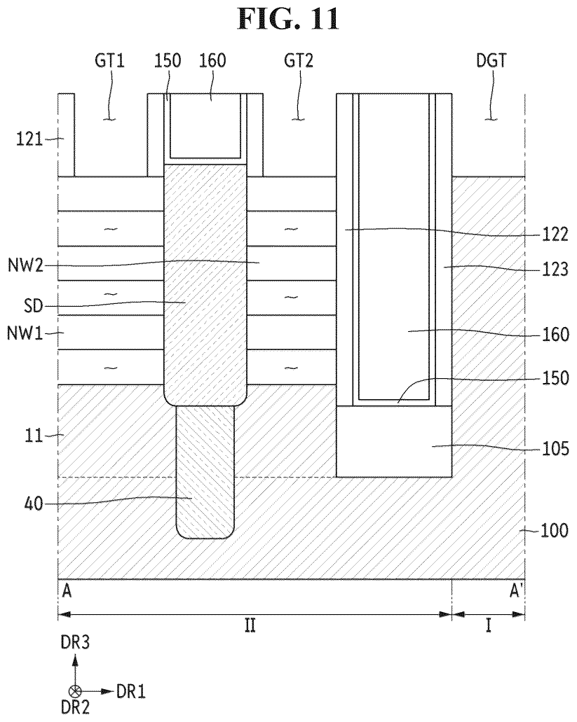

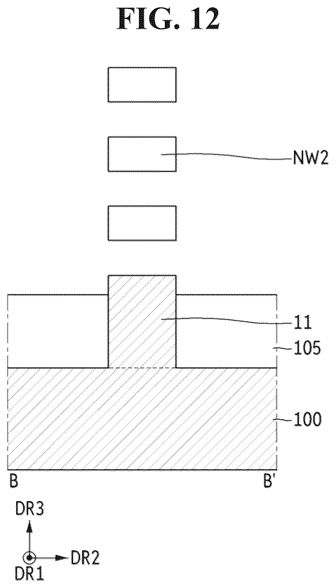

Referring to FIGS. 11 and 12, each of the first to third dummy gates (DG1, DG2, and DG3 of FIG. 10), the pad oxide layer (30 of FIG. 10), and the first semiconductor layer (21 of FIG. 10) may be etched. The portion in which the first dummy gate (DG1 of FIG. 10), the pad oxide layer (30 of FIG. 10), and the first semiconductor layer (21 of FIG. 10) are etched may be defined as a first gate trench GT1. The portion in which the second dummy gate (DG2 of FIG. 10), the pad oxide layer (30 of FIG. 10), and the first semiconductor layer (21 of FIG. 10) are etched may be defined as a second gate trench GT2. Also, the portion in which the third dummy gate (DG3 of FIG. 10) and the pad oxide layer (30 of FIG. 10) are etched may be defined as a dummy gate trench DGT.

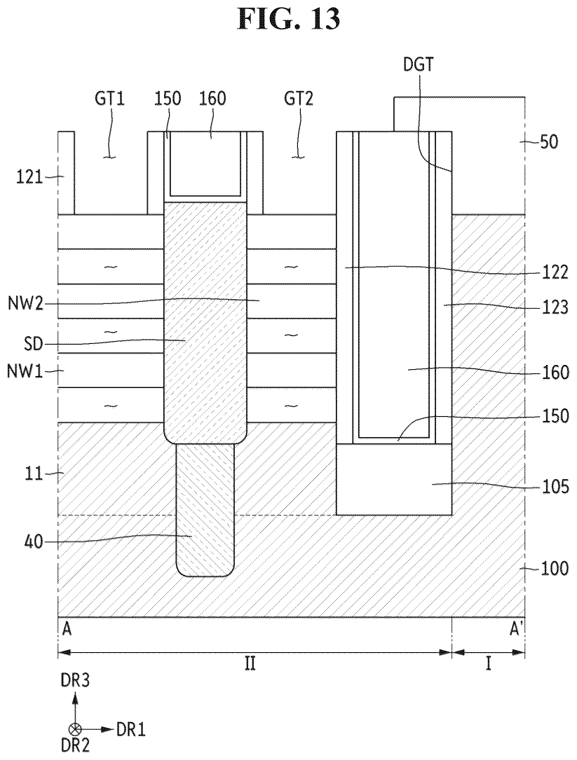

Referring to FIG. 13, a protective layer 50 may be formed to cover the upper surface of the substrate 100 formed in the first region I. The protective layer 50 may fill the dummy gate trench DGT. For example, the protective layer 50 may also be formed on the upper surfaces of each of the dummy gate spacer 123, the first etching stop layer 150, and the first upper interlayer insulating layer 160 that are adjacent to the first region I. For example, the protective layer 50 may include Spin-On Hardmask (SOH), but embodiments are not limited thereto.

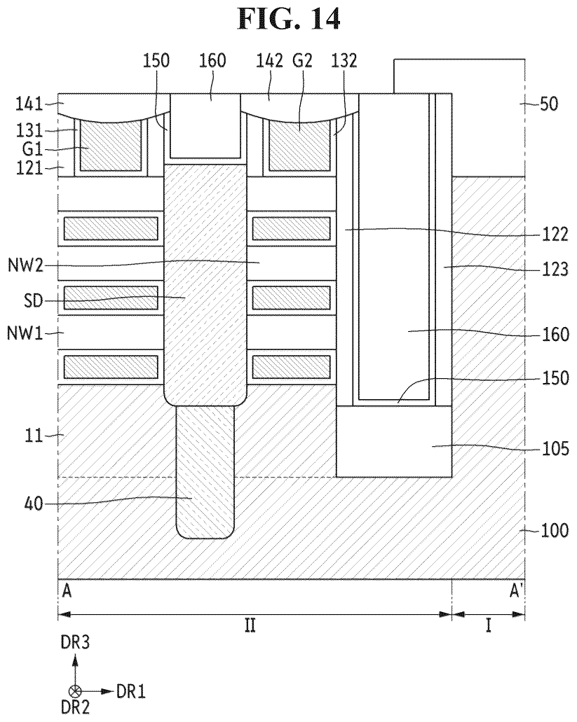

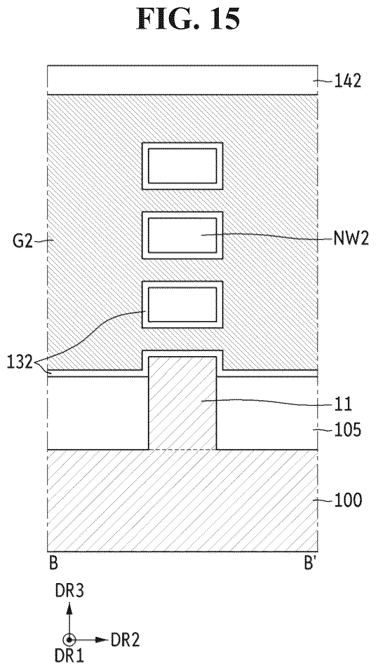

Referring to FIGS. 14 and 15, each of the first gate insulating layer 131, the first gate electrode G1, and the first capping pattern 141 may be sequentially formed inside the first gate trench (GT1 of FIG. 13). Also, each of the second gate insulating layer 132, the second gate electrode G2, and the second capping pattern 142 may be sequentially formed inside the second gate trench (GT2 of FIG. 13). For example, the first gate electrode G1 may surround the first plurality of nanosheets NW1. The second gate electrode G2 may surround the second plurality of nanosheets NW2.

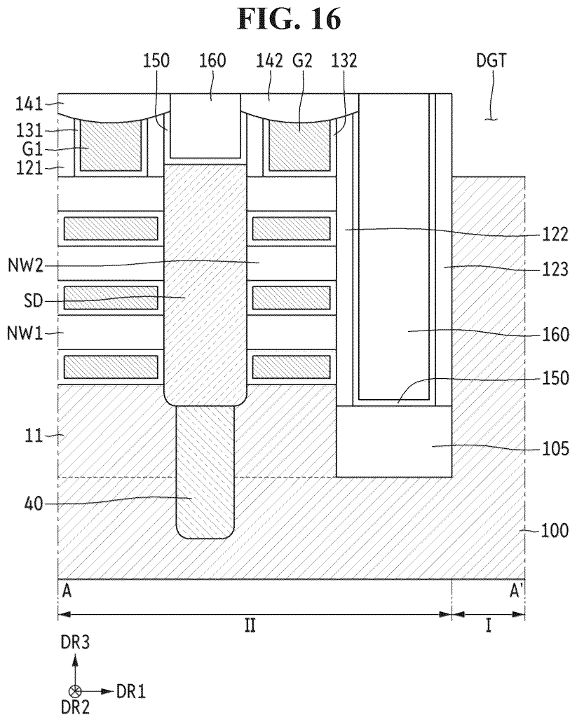

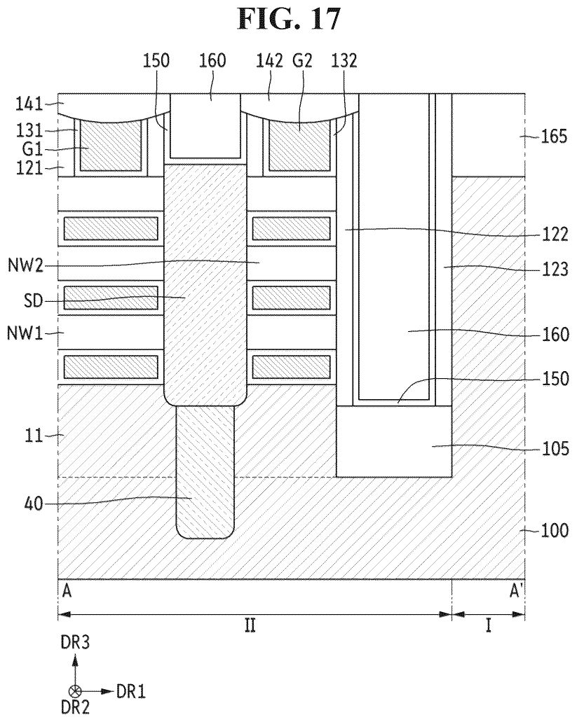

Referring to FIGS. 16 and 17, after the protective layer 50 is etched, the second upper interlayer insulating layer 165 may be formed inside the dummy gate trench DGT. For example, the upper surface of the second upper interlayer insulating layer 165 may be formed on the same plane as (e.g., may be substantially coplanar with) the upper surface of the first upper interlayer insulating layer 160.

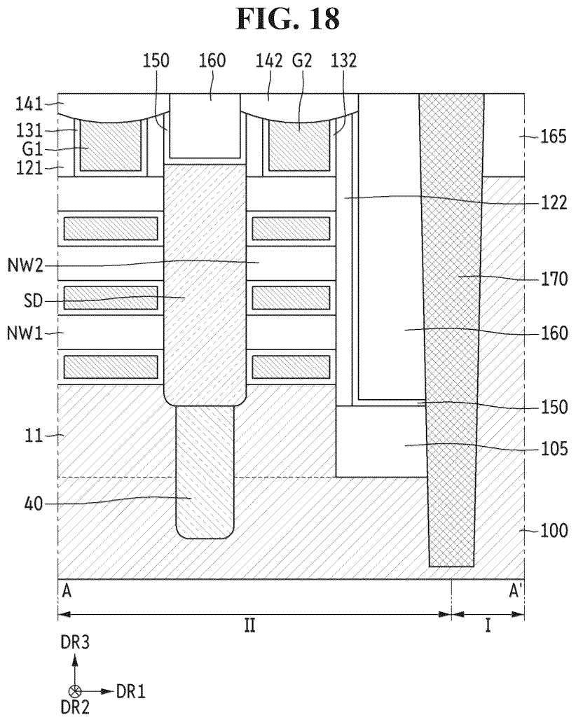

Referring to FIG. 18, the element isolation layer 170 may be formed along the boundary line between the first region I and the second region II. For example, the element isolation layer 170 may penetrate a portion of the first upper interlayer insulating layer 160, a portion of the first etching stop layer 150, the dummy gate spacer (123 of FIG. 17), a portion of the second upper interlayer insulating layer 165, a portion of the substrate 100 formed in the first region I, and a portion of the field insulating layer 105 in the vertical direction DR3. For example, the upper surface of the element isolation layer 170 may be formed on the same plane as (e.g., may be substantially coplanar with) the upper surfaces of each of the first upper interlayer insulating layer 160 and the second upper interlayer insulating layer 165. For example, the lower surface of the element isolation layer 170 may contact the substrate 100 formed on the boundary line between the first region I and the second region II.

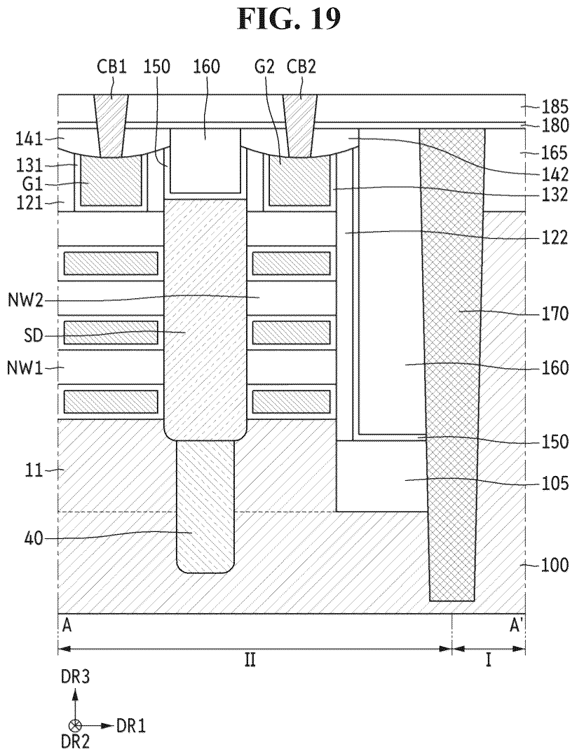

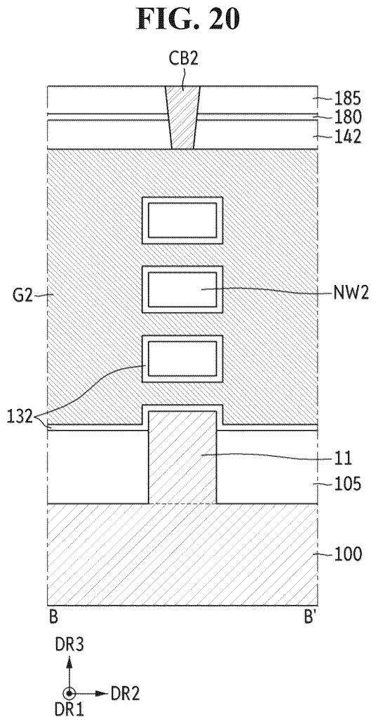

Referring to FIGS. 19 and 20, the second etching stop layer 180 and the third upper interlayer insulating layer 185 may be sequentially formed on the upper surfaces of each of the first and second capping patterns 141 and 142, the first and second upper interlayer insulating layers 160 and 165, and the element isolation layer 170. Next, a first gate contact CB1 which penetrates the third upper interlayer insulating layer 185, the second etching stop layer 180, and the first capping pattern 141 in the vertical direction DR3 and is connected to the first gate electrode G1 may be formed. Also, a second gate contact CB2 which penetrates the third upper interlayer insulating layer 185, the second etching stop layer 180, and the second capping pattern 142 in the vertical direction DR3 and is connected to the second gate electrode G2 may be formed.

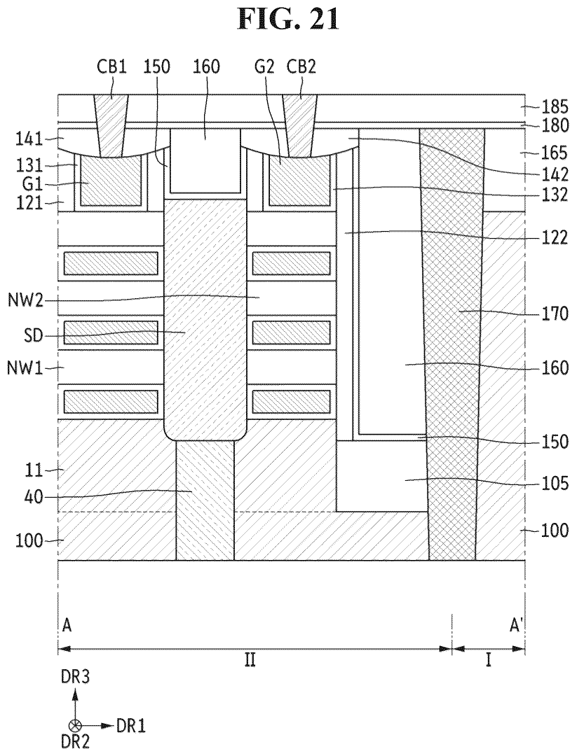

Referring to FIG. 21, a planarization process may be performed to etch a portion of each of the substrate 100, the element isolation layer 170, and the sacrificial pattern 40. After the planarization process is completed, the lower surfaces of each of the substrate 100, the element isolation layer 170, and the sacrificial pattern 40 may be formed on the same plane (e.g., may be substantially coplanar with each other). After the planarization process is completed, the lower surfaces of each of the element isolation layer 170 and the sacrificial pattern 40 may be exposed. After the planarization process is completed, the substrate 100 formed in the first region I and the substrate 100 formed in the second region II may be separated by the element isolation layer 170.

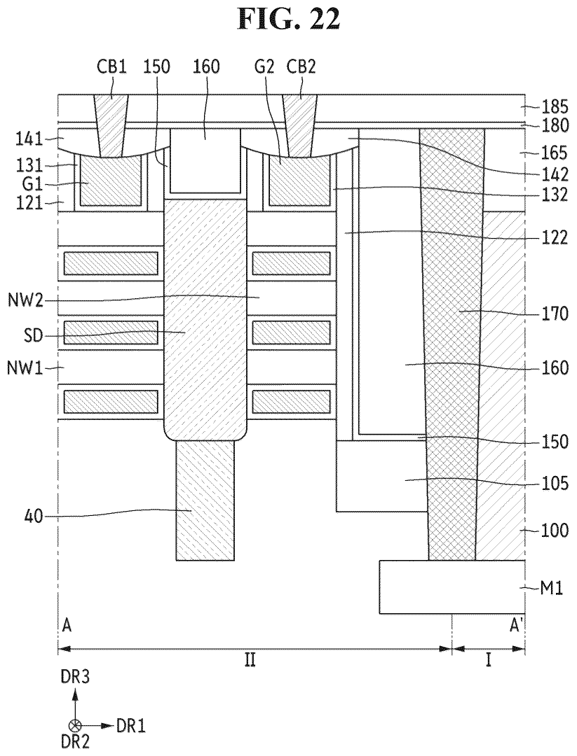

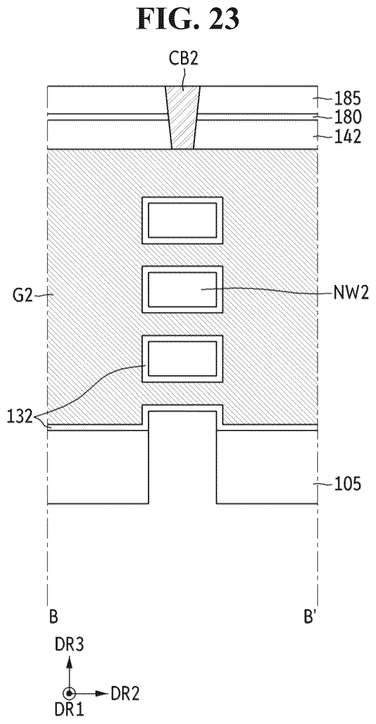

Referring to FIGS. 22 and 23, a mask pattern M1 may be formed on the lower surface of the element isolation layer 170 and the lower surface of the substrate 100 formed in the first region I. For example, the mask pattern M1 may also be formed on the lower surface of the substrate 100 formed in the second region II adjacent to the element isolation layer 170. Next, a wet etching process may be performed to etch the substrate 100 and the active pattern (11 of FIG. 21) formed in the second region II. For example, while the substrate 100 and the active pattern (11 of FIG. 21) formed in the second region II are being etched, the element isolation layer 170 and the mask pattern M1 may prevent the substrate 100 formed in the first region I from being etched.

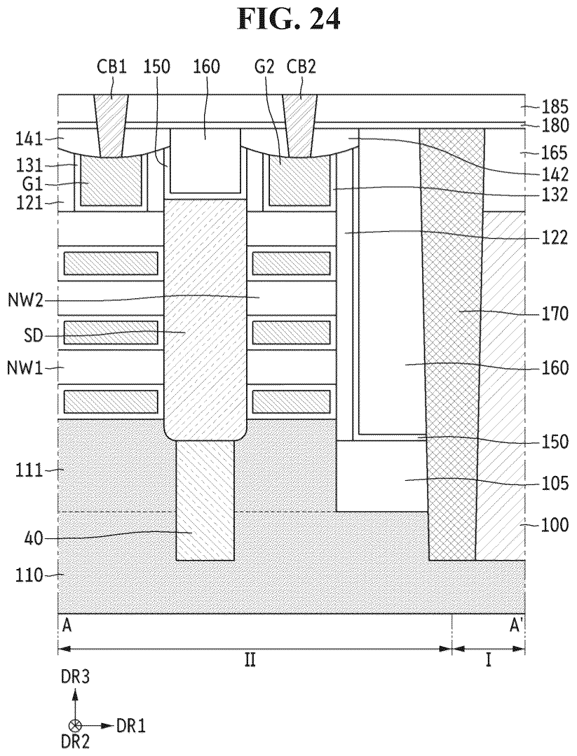

Referring to FIG. 24, the mask pattern (M1 of FIG. 22) may be removed. Thereafter, an insulating pattern 111 may be formed in the portion in which the active pattern (11 of FIG. 21) is etched. Also, a lower interlayer insulating layer 110 may be formed to cover the lower surface of the insulating pattern 111, the lower surface of the field insulating layer 105, the exposed surface of the sacrificial pattern 40, the exposed surface of the element isolation layer 170, and the lower surface of the substrate 100. In one or more embodiments, the lower interlayer insulating layer 110 may be formed to cover the mask pattern (M1 of FIG. 22), without removing the mask pattern (M1 of FIG. 22).

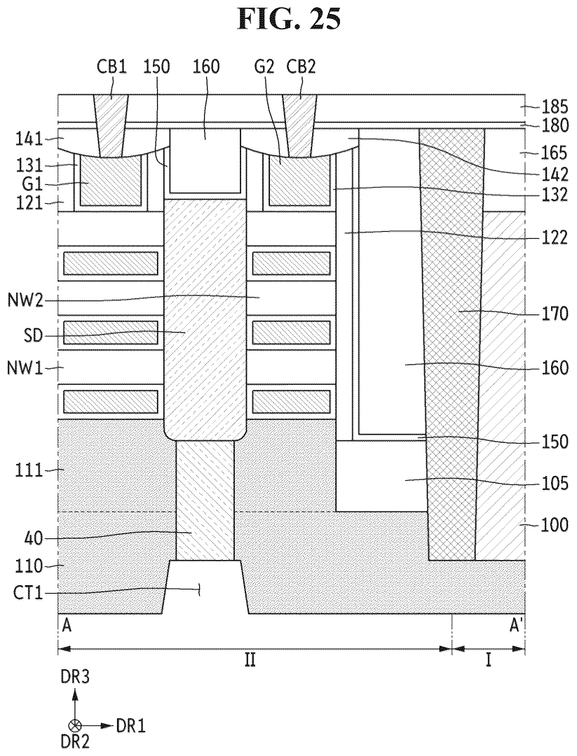

Referring to FIG. 25, a first contact trench CT1 that penetrates the lower interlayer insulating layer 110 in the vertical direction DR3 to expose the sacrificial pattern 40 may be formed.

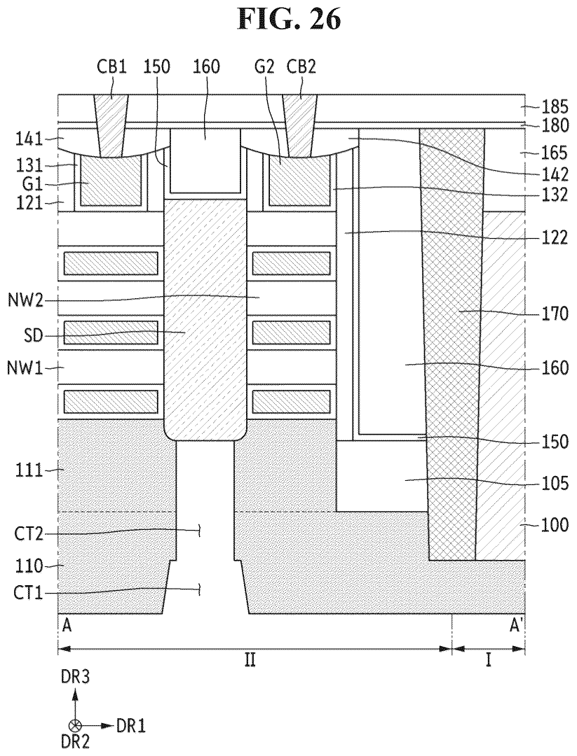

Referring to FIG. 26, the sacrificial pattern (40 of FIG. 25) may be etched through the first contact trench CT1. The portion in which the sacrificial pattern (40 of FIG. 25) is etched may be defined as a second contact trench CT2. For example, the lower surface of the source/drain region SD may be exposed through the second contact trench CT2.

Referring to FIGS. 3 and 4, a source/drain contact CA may be formed inside each of the first contact trench CT1 and the second contact trench CT2. Also, a silicide layer SL may be formed along the interface between the source/drain contact CA and the source/drain region SD. The semiconductor device shown in FIGS. 3 and 4 may be fabricated through such a fabricating process.

The method for fabricating a semiconductor device according to one or more embodiments may prevent the substrate 100 formed in the first region I from being etched, by using the element isolation layer 170, while the substrate 100 formed in the second region II is being etched. Therefore, the method for fabricating the semiconductor device according to one or more embodiments may improve the reliability of the passive elements formed in the first region I. In the semiconductor device according to one or more embodiments fabricated by such a fabricating method, the first region I may be a region in which passive elements are disposed, the second region II may be a region in which active elements such as transistors are disposed, and the second region II may be disposed to surround the first region I. The element isolation layer 170 may be disposed on the boundary line between the first region I and the second region II. That is, the element isolation layer 170 may be disposed to surround the first region I. In addition, in the semiconductor device according to one or more embodiments, the element isolation layer 170 may include a material different from the field insulating layer 105, and the lower surface of the element isolation layer 170 may be formed on the same plane as the lower surface of the substrate 100 disposed in the first region I.

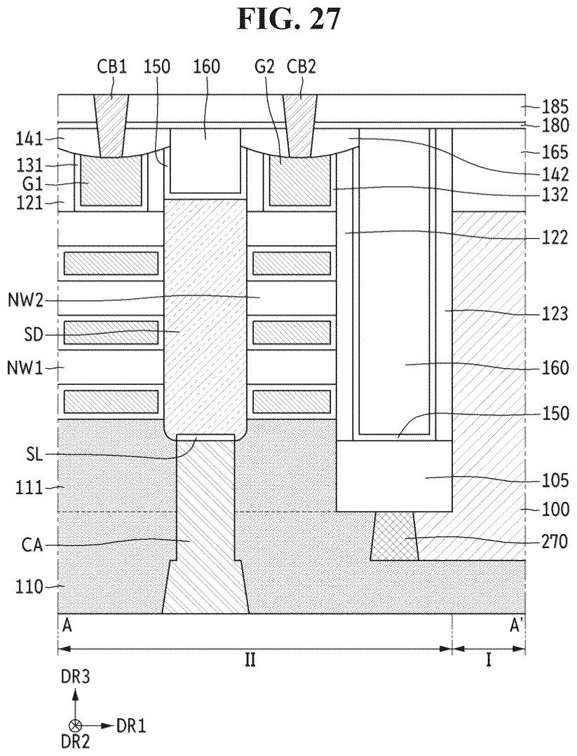

FIG. 27 is a cross-sectional view illustrating a semiconductor device according to one or more embodiments. Description of aspects that are the same as or similar to those described above may be omitted.

Referring to FIG. 27, in the semiconductor device according to one or more embodiments, the element isolation layer 270 may be disposed on the lower surface of the field insulating layer 105.

For example, the upper surface of the element isolation layer 270 may at a level that is lower than the upper surface of the field insulating layer 105 in the direction DR3. For example, the upper surface of the element isolation layer 270 may contact the upper surface of the field insulating layer 105. For example, at least a portion of the substrate 100 may contact the lower surface of the field insulating layer 105. For example, the dummy gate spacer 123 may extend in the vertical direction DR3 along the sidewall of the substrate 100 formed in the first region I.

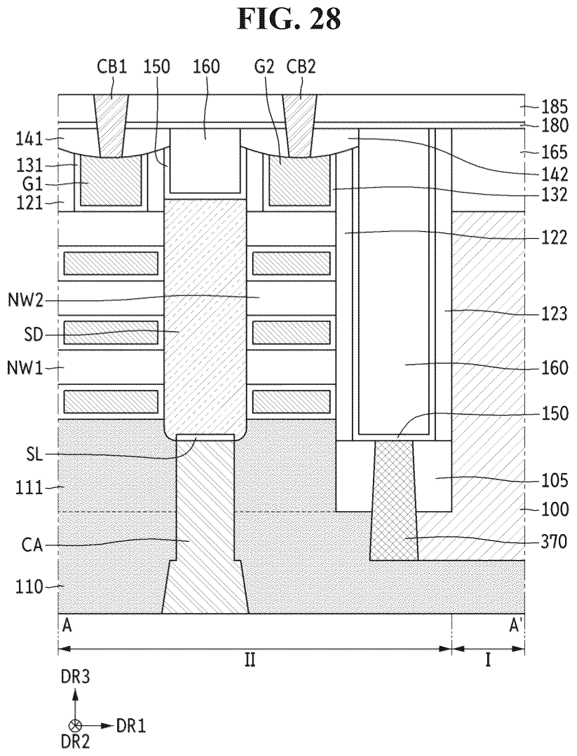

FIG. 28 is a cross-sectional view illustrating a semiconductor device according to one or more embodiments. Description of aspects that are the same as or similar to those described above may be omitted.

Referring to FIG. 28, in the semiconductor device according to one or more embodiments, an element isolation layer 370 may penetrate the field insulating layer 105 in the vertical direction DR3.

For example, a portion of the sidewall of the element isolation layer 370 may be surrounded by the field insulating layer 105. For example, the upper surface of the element isolation layer 370 may be formed on the same plane as (e.g., may be substantially coplanar with) the upper surface of the field insulating layer 105. For example, the upper surface of the element isolation layer 370 may contact the first etching stop layer 150. For example, the dummy gate spacer 123 may extend in the vertical direction DR3 along the sidewall of the substrate 100 formed in the first region I.

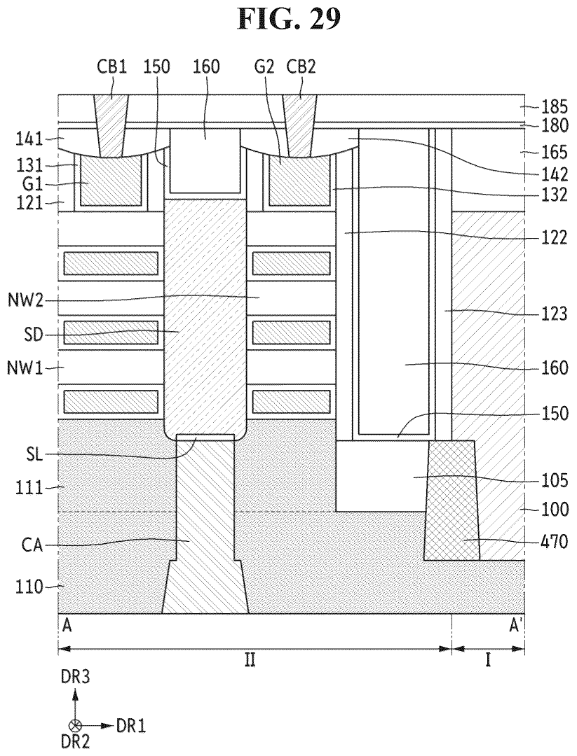

FIG. 29 is a cross-sectional view illustrating a semiconductor device according to one or more embodiments. Description of aspects that are the same as or similar to those described above may be omitted.

Referring to FIG. 29, in the semiconductor device according to one or more embodiments, an upper surface of an element isolation layer 470 may be formed on the same plane as (e.g., may be substantially coplanar with) the upper surface of the field insulating layer 105, and at least a portion of the upper surface of the element isolation layer 470 may contact the substrate 100 formed in the first region I.

For example, the dummy gate spacer 123 may extend in the vertical direction DR3 along the sidewall of the substrate 100 formed in the first region I. For example, the upper surface of the element isolation layer 470 may contact each of the first etching stop layer 150, the dummy gate spacer 123, and the substrate 100 formed in the first region I.

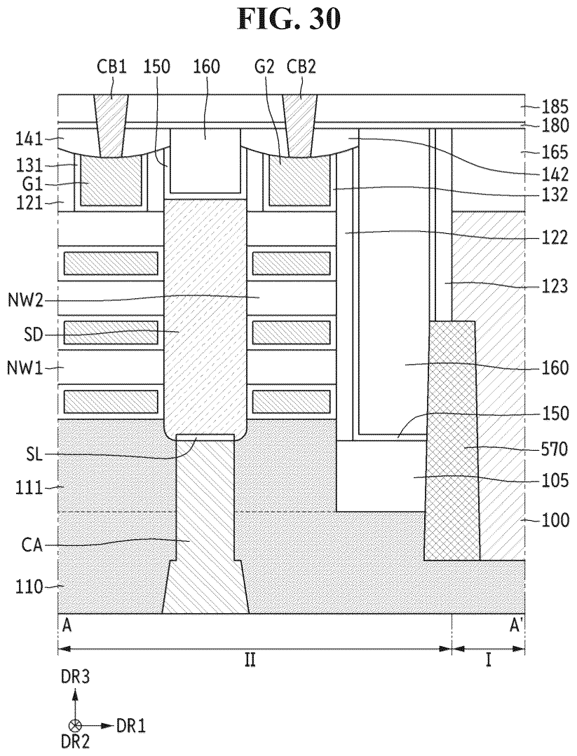

FIG. 30 is a cross-sectional view illustrating a semiconductor device according to one or more embodiments. Description of aspects that are the same as or similar to those described above may be omitted.

Referring to FIG. 30, in a semiconductor device according to one or more embodiments, an upper surface of an element isolation layer 570 may be at a level that is higher than the upper surface of the field insulating layer 105 in the direction DR3, and at least a portion of the upper surface of the element isolation layer 570 may contact the substrate 100 formed in the first region I.

For example, the dummy gate spacer 123 may extend in the vertical direction DR3 along the sidewall of the substrate 100 formed in the first region I. For example, the upper surface of the element isolation layer 570 may be at a level that is lower than the upper surface of the substrate 100 formed in the first region I in the direction DR3. For example, the upper surface of the element isolation layer 570 may contact each of the first etching stop layer 150, the dummy gate spacer 123, and the substrate 100 formed in the first region I. For example, the first sidewall of the element isolation layer 570 may contact each of the first etching stop layer 150, the first upper interlayer insulating layer 160, the field insulating layer 105, and the lower interlayer insulating layer 110.

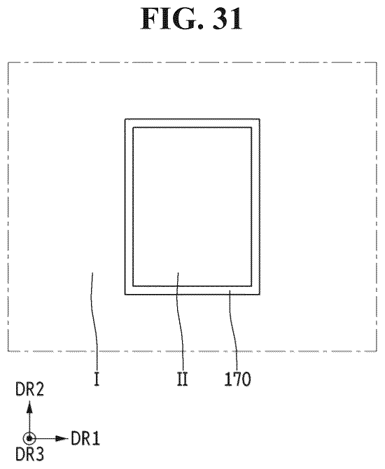

FIG. 31 is a diagram illustrating a semiconductor device according to one or more embodiments. Description of aspects that are the same as or similar to those described above may be omitted.

Referring to FIG. 31, in a semiconductor device according to one or more embodiments, the first region I may surround the second region II.

For example, the first region I may be a region in which passive elements are disposed, and the second region II may be a region in which active elements such as transistors are disposed. That is, the first region I in which passive elements are disposed may surround the second region II in which active elements are disposed. The element isolation layer 170 may be disposed on the boundary line between the first region I and the second region II. That is, the element isolation layer 170 may be disposed to surround the second region II.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a first region in which a passive element is provided;
a second region adjacent to the first region and in which an active element is provided;
a lower interlayer insulating layer in the first region and the second region;
an insulating pattern in the second region and on an upper surface of the lower interlayer insulating layer, the insulating pattern extending in a first direction;
a substrate in the first region, on the upper surface of the lower interlayer insulating layer, and spaced apart from the insulating pattern in the first direction, the substrate comprising silicon;
a field insulating layer in the second region and on the upper surface of the lower interlayer insulating layer, the field insulating layer at least partially surrounding a sidewall of the insulating pattern;
a plurality of nanosheets on the insulating pattern and spaced apart from each other in a second direction that is perpendicular to the first direction;
a gate electrode on the insulating pattern and extending in a third direction that intersects the first direction, the gate electrode at least partially surrounding the plurality of nanosheets; and
an element isolation layer on a boundary line between the first region and the second region and on the upper surface of the lower interlayer insulating layer,
wherein the element isolation layer comprises a material that is different from a material of the field insulating layer, and
wherein, in the second direction, a lower surface of the element isolation layer is at a level that is lower than a level of a lower surface of the field insulating layer.

2. The semiconductor device of claim 1, wherein at least a portion of a first sidewall of the element isolation layer contacts the lower interlayer insulating layer, and
wherein at least a portion of a second sidewall of the element isolation layer that is opposite to the first sidewall of the element isolation layer in the first direction contacts the substrate.

3. The semiconductor device of claim 1, wherein the lower surface of the element isolation layer is substantially coplanar with a lower surface of the substrate in the second direction.

4. The semiconductor device of claim 1, wherein each of the lower surface of the element isolation layer and a lower surface of the substrate contacts the lower interlayer insulating layer.

5. The semiconductor device of claim 1, further comprising a gate spacer on both sidewalls of the gate electrode in the first direction,
wherein the gate spacer contacts sidewalls of the plurality of nanosheets that face the substrate in the first direction.

6. The semiconductor device of claim 1, further comprising:
a source/drain region on the insulating pattern; and
a source/drain contact connected to the source/drain region and penetrating the lower interlayer insulating layer and the insulating pattern in the second direction,
wherein the element isolation layer extends downward in the second direction to a first level, and
wherein the source/drain contact extends downward in the second direction to a second level that is lower than the first level.

7. The semiconductor device of claim 1, wherein an upper surface of the element isolation layer is at a level that is higher than a level of an uppermost surface of the gate electrode in the second direction.

8. The semiconductor device of claim 1, further comprising:
a dummy gate spacer on an upper surface of the field insulating layer and extending in the second direction along a sidewall of the substrate.

9. The semiconductor device of claim 1, wherein at least a portion of a sidewall of the element isolation layer contacts the field insulating layer.

10. The semiconductor device of claim 1, wherein an upper surface of the element isolation layer is at a level that is higher than a level of an upper surface of the field insulating layer in the second direction.

11. The semiconductor device of claim 1, wherein the second region surrounds the first region.

12. The semiconductor device of claim 1, wherein the first region surrounds the second region.

13. A semiconductor device comprising:
a first region in which a passive element is provided;
a second region surrounding the first region and in which an active element is provided;
a lower interlayer insulating layer in the first region and the second region;
an insulating pattern in the second region and on an upper surface of the lower interlayer insulating layer, the insulating pattern extending in a first direction;
a substrate in the first region, on the upper surface of the lower interlayer insulating layer and spaced apart from the insulating pattern in the first direction, the substrate comprising silicon;
a field insulating layer in the second region and on the upper surface of the lower interlayer insulating layer, the field insulating layer at least partially surrounding a sidewall of the insulating pattern;
a gate electrode on the insulating pattern and extending in a second direction that intersects the first direction;
a source/drain region on the insulating pattern;
a source/drain contact connected to the source/drain region and penetrating the lower interlayer insulating layer and the insulating pattern in a third direction that is perpendicular to the first direction and the second direction; and
an element isolation layer on a boundary line between the first region and the second region and on the upper surface of the lower interlayer insulating layer,
wherein the element isolation layer comprises a material that is different from a material of the field insulating layer,
wherein a lower surface of the element isolation layer is at a level that is lower than a level of a lower surface of the field insulating layer in the third direction,
wherein the lower surface of the element isolation layer is substantially coplanar with a lower surface of the substrate,
wherein the element isolation layer extends downward in the third direction to a first level, and
wherein the source/drain contact extends downward in the third direction to a second level that is lower than the first level.

14. The semiconductor device of claim 13, wherein an upper surface of the substrate is at a level that is higher than a level an uppermost surface of the insulating pattern in the third direction.

15. The semiconductor device of claim 13, further comprising:
a plurality of nanosheets on the insulating pattern and spaced apart from each other in the third direction,
wherein the plurality of nanosheets are at least partially surrounded by the gate electrode.

16. The semiconductor device of claim 13, wherein an upper surface of the element isolation layer contacts the lower surface of the field insulating layer.

17. The semiconductor device of claim 13, wherein at least a portion of an upper surface of the element isolation layer contacts the substrate.

18. The semiconductor device of claim 13, further comprising:
a dummy gate spacer on an upper surface of the field insulating layer and extending in the third direction along a sidewall of the substrate.

19. The semiconductor device of claim 18, wherein at least a portion of an upper surface of the element isolation layer contacts the dummy gate spacer.

20. A semiconductor device comprising:
a first region in which a passive element is provided;
a second region surrounding the first region and in which an active element is provided;
a lower interlayer insulating layer in the first region and the second region;
an insulating pattern in the second region and on an upper surface of the lower interlayer insulating layer, the insulating pattern extending in a first direction;
a substrate in the first region, on the upper surface of the lower interlayer insulating layer, and spaced apart from the insulating pattern in the first direction, wherein the substrate comprises silicon, and an upper surface of the substrate is at a level that is higher than a level of an uppermost surface of the insulating pattern in a second direction that is perpendicular to the first direction;
a field insulating layer in the second region and on the upper surface of the lower interlayer insulating layer, the field insulating layer at least partially surrounding a sidewall of the insulating pattern;
a plurality of nanosheets on the insulating pattern and spaced apart from each other in the second direction;
a gate electrode on the insulating pattern and extending in a third direction that intersects the first direction, the gate electrode at least partially surrounding the plurality of nanosheets;
a gate spacer on both sidewalls of the gate electrode in the first direction, the gate spacer contacting sidewalls of the plurality of nanosheets that face the substrate in the first direction;
a source/drain region on the insulating pattern;
a source/drain contact connected to the source/drain region and penetrating the lower interlayer insulating layer and the insulating pattern in the second direction; and
an element isolation layer on a boundary line between the first region and the second region and on the upper surface of the lower interlayer insulating layer,
wherein the element isolation layer comprises a material that is different from a material of the field insulating layer,
wherein a lower surface of the element isolation layer is at a level that is lower than a level of a lower surface of the field insulating layer in the second direction,
wherein the lower surface of the element isolation layer is substantially coplanar with lower surface of the substrate,
wherein an upper surface of the element isolation layer is at a level that is higher than a level of an uppermost surface of the gate electrode in the second direction,
wherein the element isolation layer extends downward in the second direction to a first level, and
wherein the source/drain contact extends downward in the second direction to a second level that is lower than the first level.
